(19) United States
(12) Patent Application Publication
(10) Pub. No.: US 2008/0145960 A1
(43) Pub. Date: Jun. 19, 2008

(54) Super thin LED package for the backlighting applications and fabrication method

(75) Inventors: Boris Kolodin, Beachwood, OH (US); Ivan Eliashevich, Maplewood, NJ (US); Chen-Lun Hsing Chen, Sanchong City (TW); Stanton E. Weaver, Northville, NY (US)

Correspondence Address: Scott A. McCollister, Esg.;Fay, Sharpe, Fagan, Minnich & McKee, LLP, Seventh Floor, 1100 Superior Avenue, Cleveland, OH, 44114-2579, US

(73) Assignee: GELcore, LLC

(21) Appl. No.: 11/639,759

(22) Filed: Dec. 15, 2006

(51) Int. Cl. H01L 21/00

(52) U.S. Cl. 438/28

(57) ABSTRACT

First and second light emitting diode (LED) arrays, which each includes a corresponding number of LED dies, are disposed on a substrate proximately and substantially parallel to one another. Each pair of substantially paralleled LED dies of the first and second arrays is covered by substantially transparent optical encapsulant. The optical encapsulant is one of covered by a reflective layer for a UV to visible spectral region and shaped for total internal light reflection. The substrate is diced along an axis extending in parallel and between the first and second LED arrays.

### BACKGROUND

The present application relates to the lighting arts. It finds particular application in conjunction with the light emitting diode (LED) backlighting systems for the LCD displays, and will be described with particular reference thereto. However, it is to be appreciated that the present application is also amenable to other like applications.

Light emitting diodes have been increasingly used as the light source of a backlight module for the LCD displays. Backlighting light emitting diodes provide a given display luminance in small reliable packages. Light emitting diodes have been developed in many colors spanning the visible spectrum and extending into the infrared and ultraviolet region. Typically, the LED-based backlight is positioned in a cavity. The cavity is commonly constructed of a white diffusely reflecting material of high reflectivity and is covered with some type of a diffusive, reflective surface. The LED light source is coupled to an edge of the cavity to provide a sideways illumination. A light guide is typically coupled adjacent to the cavity to collect light emitted by the LED and direct it toward the light output surface. The LCD display is positioned in front of the light guide.

One requirement for the LED backlight is high light output intensity as the display must be sufficiently and uniformly illuminated. Another requirement for the LED backlight is the thinness of the LED package for efficient coupling with the light guide and conforming to overall thin dimensions of the display unit. Typical miniature white backlighting LED package incorporates flat silver-plated lead frame and molded plastic reflector with fence geometry. For example, such package has 2.8×1.2×1 mm dimensions. The 1 mm thickness of the LED package can be minimized by decreasing the thickness of the plastic walls. However, decreasing the thickness of the plastic walls causes excessive light leakage and accordingly decreases the intensity of the LED package light output.

Another problem is associated with so called “double packaging” approach. Typically, a small LED backlighting package is soldered to the substrate at customer site. Such double packaging is inefficient and time consuming.

There is a need for methods and apparatuses that overcome the above referenced problems and others.

### BRIEF DESCRIPTION

In accordance with one aspect of the present application, a method is disclosed. First and second light emitting diode (LED) arrays, which each includes a corresponding number of LED dies, are disposed on a substrate proximately and substantially parallel to one another. Each pair of substantially paralleled LED dies of the first and second arrays are covered by substantially transparent optical encapsulant. The optical encapsulant is one of covered by a reflective layer for a UV to visible spectral region and shaped for total internal reflection. The substrate is diced along an axis extending in parallel and between the first and second LED arrays.

In accordance with another aspect of the present application, a method of fabricating a thin light emitting diode (LED) backlight is disclosed. A substrate is fabricated. A first metal layer is disposed on a first surface of a layer of flexible material. A second metal layer is disposed on a second surface of the layer of flexible material. A first LED array, which includes at least two LED dies, is disposed proximately to the first metal layer. A second LED array, which includes a number of LED dies equal to a number of the first array LED dies, is disposed proximately to the first metal layer in close proximity and substantially parallel to the first array. Each pair of substantially paralleled LED dies of the first and second arrays is covered by substantially transparent optical encapsulant. A reflective layer is disposed about optical encapsulant or the shape of optical encapsulant is designed for total internal reflection eliminating the need for the reflective layer. The substrate is diced along an axis extending in parallel and between the first and second LED arrays.

In accordance with another aspect of the present application, a light emitting diode (LED) package is disclosed. A substrate includes a layer of a flexible material. A first metal layer is disposed on a first surface of the flexible layer. A second metal layer is disposed on a second surface of the flexible layer. A LED die is disposed about the first metal layer and covered by substantially transparent optical encapsulant which is covered by a reflective layer for a UV to visible spectral region or the shape of optical encapsulant is designed for total internal reflection eliminating the need for the reflective layer, a thickness of the LED package is less than or equal to about 600 um.

### BRIEF DESCRIPTION OF THE DRAWINGS

FIG. 1 is a diagrammatic illustration of a side view of a back-lighting module;

FIG. 2 is a diagrammatic illustration of a top view of a backlighting module;

FIG. 3 is a diagrammatic illustration of an LED package;

FIG. 4 is a diagrammatic illustration of a top view of an LED assembly for parallel connecting of the LEDs; and

FIG. 5 is a diagrammatic illustration of a top view of an LED assembly for serial connection of the LEDs.

### DETAILED DESCRIPTION

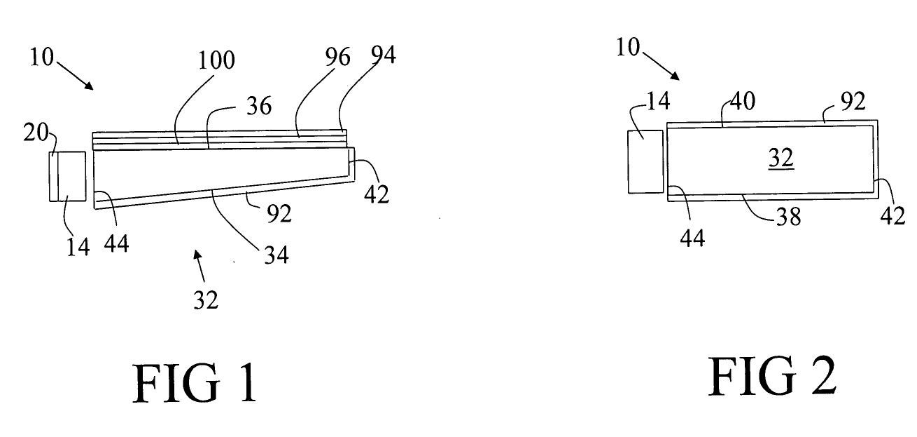

With reference to FIGS. 1 and 2, a light emitting diode (LED) backlight module 10 includes at least one LED or LED chip 14 disposed on a substrate 20. For example, the LED 14 may include any semiconductor visible or UV light source that is capable of producing, when combined with the phosphor composition, white light. For example, the LED 14 may include at least one semiconductor layer including GaN, ZnSe or SiC. In the preferred embodiments, the emission of the LEDs generally have a wavelength in the range from about 250 to about 650 nm, which corresponds to an emission range from UV to red. Typically, the LED is doped with various impurities. Thus, the LED may comprise a semiconductor diode based on any suitable III-V, II-VI or IV-IV semiconductor layers and having an emission wavelength of about 250 to 650 nm. In a preferred embodiment, the LED emits at a peak wavelength of from about 350 to 500 nm, and preferably from about 350 to 450 nm. Thus, in a preferred embodiment, the LED module includes a near-UV to blue emitting LED.

A light guide 32 is coupled to the LEDs 14. The light guide 32 may be an optically transmissive monolithic wedge including a back surface 34, a light output surface 36 and side surfaces 38, 40. An end surface 42 is disposed opposing an input surface 44. Although shown as a wedge in this embodiment, it is contemplated that the light guide 32 may be any shape, as for example, a slab or a pseudo-wedge. The back surface 34 and output surface 36 are substantially planar. The back surface 34 converges at the wedge angle toward the output surface 36 to propagate the light injected into the input surface 44 by the LEDs 14 toward the end surface 42 by total internal reflection (TIR) and for the extraction of light by frustration of the TIR.

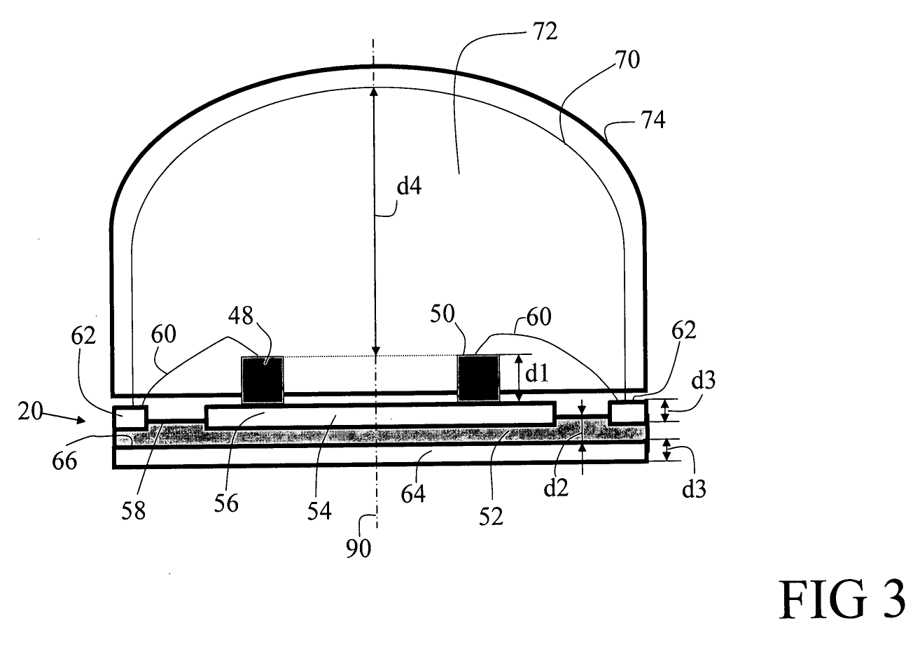

With reference to FIG. 3, a pair of bilateral LED dies 48, 50 is disposed on the substrate 20. A height dl of each LED die 48, 50 is, for example, 115 um. The substrate 20 includes a core layer 52 of a flexible material such as polyimide. For example, a thickness d2 of the core layer 52 is about 25 um. For example, a bottom contact (not shown) of each LED die 48, 50 is attached or bonded to a first bonding pad 54 of a first or interconnection layer 56 which is disposed about an LED mounting side 58 of the core layer 52. A wire 60 connects a top contact (not shown) of the LED dies 48, 50 to a corresponding second bonding pad 62 of the interconnection layer 56. As another example, the LED dies 48, 50 are flip chip bonded to the first or interconnection layer 56. A second or light stopping layer 64 is disposed about a rear side 66 of the core layer 52 to prevent leakage of light emitted by the LED dies 48, 50. For example, the first and second layers 56, 64 include metal such as copper. In one embodiment, a thickness d3 of the first and second layers 56, 64 is about 5 um. In another embodiment, the thickness d3 of the first and second layers 56, 64 is about 12 um. Of course, it is contemplated that the first and second layers 56, 64 can have thicknesses different from one another. An optically transparent encapsulant 70 surrounds the LED dies 48, 50 to direct the light generated by the LED dies 48, 50 toward the light guide 32. A diameter of the encapsulant 70 is less than or equal to about 1500 um, for example, 1000 um. A gap d4 between the encapsulant 70 and LED dies 48, 50 is less than or equal to about 625 um. For example, in one embodiment, the gap d4 between the encapsulant 70 and LED dies 48, 50 is equal to about 350 um. In another embodiment, the gap d4 between the encapsulant 70 and LED dies 48, 50 is equal to about 336 um. The reflector layer 74 is disposed about the optically transparent encapsulant 70. Alternatively, the shape of the optical encapsulant 70 is designed for total internal reflection eliminating the need for the reflective layer. In one embodiment, the encapsulant 70 includes a reflective film that wraps around the LED light source forming a cavity 72. In one embodiment, the cavity 72 includes a composition of phosphor and soft glass. The applicable phosphors are described below.

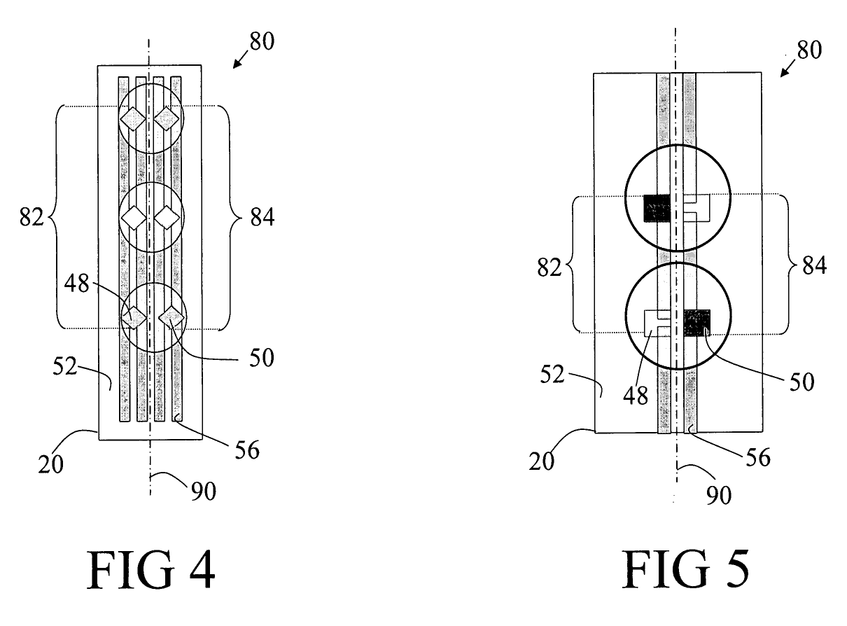

With continuing reference to FIG. 3 and further reference to FIG. 4, an LED strip 80 includes a first LED array 82 including the LED dies 48 and a second LED array 84 including the LED dies 50, disposed on the substrate 20 in close proximity to each other. Individual LED dies 48, 50 of the LED arrays 82, 84 are disposed in approximately same lateral position. Each LED array 82, 84 includes a number n of the LED dies 48, 50 connected in parallel. The number n of the LED dies 48, 50 is identical in each LED array 82, 84 and, for example, is two, three, four, five, etc. Each pair of bilateral LED dies 48, 50 of each array 82, 84 is covered by the encapsulant 70 and reflector 74. The LED strip 80 is diced along an axis 90, parallel to the arrays 82, 84 and disposed in between pairs of opposing LED dies 48, 50, to form single side LED chip 14 or an array of a single side LED chips 14. Depending on the dicing method, heat treatment or another polishing treatment of the optical face may be required. For example, the dicing is performed by laser cutting which provides a benefit of cutting and polishing in one step. Of course, it is contemplated that dicing can be performed by saw cutting, wire cutting, and other appropriate techniques.

With continuing reference to FIG. 3 and further reference to FIG. 5, in this embodiment, the LED dies 48, 50 are connected in series.

With reference again to FIG. 1, in one embodiment, a high efficiency specular reflective layer 92 is disposed at least on one of the back, side and surfaces 34, 38, 40, 42. For example, the reflective layer 92 is at least 85% reflective, more preferably 95% reflective and most preferably greater than 97% reflective, i.e., less than 3% absorptive losses. In one embodiment, the reflective layer 92 is a mirror film that is directly secured, such as by lamination using an adhesive, to the surfaces. Such reflector layers are known and may include, e.g., a high reflective visible mirror product available from the Minnesota Mining and Manufacturing (3M) Company of St. Paul, Minn., that is formed of numerous polymeric layers. In another embodiment, the reflective layer 46 may be a film formed by the vacuum deposition of numerous layers of polymeric material. Such a film would require numerous layers wherein particular layers are arranged to reflect particular light wavelengths. In still another embodiment, the reflective layer may be a reflective tape, such as Mylar or some other material. In yet another embodiment, the reflective layer includes a tape member including a ZrO2 filled silicon layer on the side facing the light guide and TiO2 impregnated polymer with Ag on the side facing away from the light guide.

The lamination of the reflective layer 92 to the surfaces 34, 38, 40, 42 may be accomplished by adhesive bonding using UV cure, pressure sensitive or other suitable adhesives. Alternatively, the reflective layer 92 may be formed on the surfaces using a deposition process, e.g., a metal deposition process, or other methods of laying down reflective surface. Directly securing the reflective layer 92 to the surfaces 34, 38, 40, 42 provides an efficient specular reflector that retains the TIR containment of the light being guided.

In one embodiment, a light diffusion plate 94 is provided on a top of the output surface 36 of the light guide 32. The light diffusion plate 94 may be formed using a transparent resin sheet dispersed with other material having different refractive index or a transparent sheet having an uneven surface. For example, the diffusion plate 94 may be formed integrally with the light guide 32 by the inclusion of diffusive particles within the body of the light guide 32, or, as another example, a diffusive film may be directly secured, such as by adhesive bonding, to the output surface 36 of the light guide 32.

Additional optional light directing optical components may also be included in the backlighting module 10. Such additional light directing optics may include, for example, waveguides, brightness enhancing films, prism, etc.

In one embodiment, a radiation reflection layer 96 for selectively reflecting radiation having a specific wavelength is included in the backlighting module 10. For example, the reflection layer 96 is disposed between the output surface 36 and the diffusion layer 94. Such reflection layer 96 is especially desirable when the LED 14 is a near-UV emitting LED. The emission of appreciable amounts of UV light from the light guide 32 is generally not desirable and does not contribute to the emission intensity in the visible spectrum. The use of a UV reflection layer on top of the light guide 32 directs any UV light not absorbed by the radiation converting material (discussed below) back into the light guide 32 while allowing radiation of different wavelengths (such as that emitted by the phosphor) to pass. Such radiation reflection layers are known in the art and may include reflective multilayer thin film metal based materials.

In one embodiment, a fluorescent radiation converting material is disposed as a phosphor layer 100 about the output surface 36. The radiation conversion material can also be placed in other layers, such as in the light diffusion layer 94 or the radiation reflection layer 96 and can also be coated on one or more of the side and end surfaces of the light guide. The radiation converting material is designed to absorb the radiation emitted by the LED 14, either in whole or in part, and emit radiation at a different wavelength. The radiation converting material may be any suitable radiation converting material capable of absorbing the radiation emitted by the LED chip and emitting radiation in a desired spectral region.

Suitable phosphor compositions should be chosen based on the emission profile of the LED chosen as the light source for the backlight as well as the desired output characteristics of the backlight. That is, if a UV emitting LED is chosen as the light source, then a phosphor that displays a strong absorption in the UV region should be chosen for efficient conversion. Likewise, phosphors should also be chosen based on the color point and other characteristics desired in the output of the backlight. Thus, for example, if a white light emitting backlight system is desired, the specific phosphor composition should be selected such that the output is white colored. The phosphors can be organic or inorganic.

The relative amounts of each phosphor in the phosphor material can be described in terms of spectral weight. The spectral weight is the relative amount that each phosphor contributes to the overall emission spectrum of the phosphor material, as necessary to achieve the desired color of the light emitted by the package. The spectral weight amounts of all the individual phosphors should add up to unity. In one embodiment, a phosphor material comprises a spectral weight of from about 0 to about 0.50 of an optional phosphor with an emission maximum from about 430 um to about 500 um (which would not be needed for excitation with a blue or blue-green LED having an emission maximum from about 430 um to about 500 um), and the balance of the material being a phosphor with an emission maximum from about 500 um to about 610 um, to produce white light. Garnets activated with at least Ce³⁺, such as yttrium aluminum garnet (YAG:Ce), terbium aluminum garnet (TAG:Ce) and appropriate compositional modifications thereof known in the art, are particularly preferred phosphors with an emission maximum from about 500 um to about 610 um. In another embodiment, other phosphors with an emission maximum from about 500 um to about 610 um are alkaline earth orthosilicates activated with at least Eu²⁺, e.g. (Ba,Sr,Ca)₂SiO₄: Eu²⁺ (“BOS”) and appropriate compositional modifications thereof known in the art.

It is contemplated that various phosphors which are described in this application in which different elements enclosed in parentheses and separated by commas, such as (Ba,Sr,Ca)₂SiO₄: Eu²⁺ can include any or all of those specified elements in the formulation in any ratio. For example, the phosphor identified above has the same meaning as (BaₐSr_{b}Ca_{1-a-b})₂SiO₄: Eu²⁺, where a and b can each vary such that the total value of a and b may assume values from 0 to 1, including the values of 0 and 1.

Depending on the identity of the specific phosphors, exemplary backlight module system 10, for example, produces white light having general color rendering index (Ra) values greater than 70, preferably>80, and correlated color temperature (CCT) values less than 6500K.

In addition, other phosphors emitting throughout the visible spectrum region, may be used in the phosphor material to customize the color of the resulting light and produce sources with improved light quality. While not intended to be limiting, suitable phosphors for use in the blend with the present phosphors include:
(Ba,Sr,Ca,Zn)₅(PO₄)₃(Cl,F,Br,OH):Eu²⁺ (SECA)
(Ba,Sr,Ca)BPO₅:Eu²⁺
(Sr,Ca)₁₀(PO₄)₆*νB₂O₃:Eu²⁺ (wherein 0<ν≦1)
Sr₂Si₃O₈*2SrCl₂: Eu²⁺
(Ca,Sr,Ba)₃MgSi₂O₈:Eu²⁺
BaAl₈O₁₃:Eu²⁺
2SrO*0.84P₂O₅*0.16B₂O₃:Eu²⁺
(Ba,Sr,Ca)MgAl₁₀O₁₇:Eu²⁺ (BAM)
(Ba,Sr,Ca)Al₂O₄:Eu²⁺
(Ba,Sr,Ca)₂Si_{1-ξ}O_{4-2ξ}:Eu²⁺ (wherein 0≦ξ≦0.2)
(Ba,Sr,Ca)₂(Mg,Zn)Si₂O₇:Eu²⁺
(Sr,Ca,Ba)(Al,Ga,In)₂S₄:Eu²⁺
(Y,Gd,Tb,La,Sm,Pr,Lu)₃(Sc,Al,Ga)_{5-α}O_{12-3/2α}:Ce³⁺ (wherein 0≦α≦0.5)
(Lu,Sc,Y,Tb)₂₋ᵤ₋ᵥCeᵥCa₁₊ᵤLi_{w}Mg_{2-w}P_{w}(Si,Ge)_{3-w}O_{12-u/2} (where −0.5≦u≦1; 0<v≦0.1; and 0≦w≦0.2)
(Ca,Sr)₈(Mg,Zn)(SiO₄)₄Cl₂: Eu²⁺
(Sr,Ca,Ba,Mg,Zn)₂P₂O₇:Eu²⁺
(Ca,Sr)S:Eu²⁺,Ce³⁺
SrY₂S₄:Eu²⁺
CaLa₂S₄:Ce³⁺
(Ba,Sr,Ca)MgP₂O₇: Eu²⁺
(Ba,Sr,Ca)_{β}Si_{γ}N_{μ}:Eu²⁺ (wherein 2β+4γ=3μ)
Ca₃(SiO₄)Cl₂: Eu²⁺
(Y,Lu,Gd)_{2-φ}Ca_{φ}Si₄N_{6+φ}C_{1-φ}:Ce³⁺ (wherein 0≦φ≦0.5)
(Lu,Ca,Li,Mg,Y)alpha-SiAlON: Eu²⁺,Ce³⁺
(Ca,Sr,Ba)SiO₂N₂:Eu²⁺,Ce³⁺
3.5MgO*0.5MgF₂*GeO₂:Mn⁴⁺
Ca_{1-c-f}Ce_{c}Eu_{f}Al_{1+c}Si_{1-c}N₃ (wherein 0<c≦0.2, 0≦f≦0.2)
Ca₁₋ₕ₋ᵣCeₕEuᵣAl₁₋ₕ(Mg,Zn)ₕSiN₃(wherein 0<h≦0.2, 0≦r≦0.2)
Ca₁₋₂ₛ₋ₜCeₛ(Li,Na)ₛEuₜAlSiN₃ (wherein 0≦s≦0.2, 0≦f≦0.2, s+t>0)
Ca_{1-σ-χ-φ}Ce_{σ}(Li,Na)_{χ}Eu_{φ}Al_{1+σ-χ}Si_{1-σ+χ}N₃ (wherein 0≦σ≦0.2, 0<χ≦0.4, 0≦φ≦0.2)

It is contemplated that when a phosphor has two or more dopant ions (i.e. those ions following the colon in the above compositions), the phosphor has at least one (but not necessarily all) of those dopant ions within the material. E.g., the phosphor can include any or all of those specified ions as dopants in the formulation.

When the phosphor composition includes a blend of two or more phosphors, the ratio of each of the individual phosphors in the phosphor blend may vary depending on the characteristics of the desired light output. The relative proportions of the individual phosphors in the various phosphor blends may be adjusted to produce visible light of predetermined x and y values on the CIE chromaticity diagram. The produced white light may, for instance, possess an x value in the range of about 0.30 to about 0.55, and a y value in the range of about 0.30 to about 0.55. In the preferred embodiment, the color point of the white light lies on or substantially on the Planckian (also known as the blackbody) locus), e.g. within 0.020 units in the vertical (y) direction of the 1931 CIE chromaticity diagram, more preferably within 0.010 units in the vertical direction. Of course, it is contemplated that the identity and amounts of each phosphor in the phosphor composition can be varied according to the needs of the particular end user. Since the efficiency of individual phosphors may vary widely between suppliers, the exact amounts of each phosphor needed are best determined empirically, e.g. through standard design of experimental (DOE) techniques.

In one embodiment, the phosphor blend of BOS phosphor and a blue phosphor (e.g. SECA or BAM identified above) provides light conversion from ultraviolet to white light for a group III-nitride light emitting diodes.

The present application has been described with reference to the preferred embodiments. Obviously, modifications and alterations will occur to others upon reading and understanding the preceding detailed description. It is intended that the application be construed as including all such modifications and alterations insofar as they come within the scope of the appended claims or the equivalents thereof.

1. A method comprising:
disposing first and second light emitting diode (LED) arrays, which each includes a corresponding number of LED dies, on a substrate proximately and substantially parallel to one another;
covering each pair of substantially paralleled LED dies of the first and second arrays by substantially transparent optical encapsulant;
one of covering the optical encapsulant by a reflective layer for a UV to visible spectral region and shaping the optical encapsulant for total internal reflection; and
dicing the substrate along an axis extending in parallel and between the first and second LED arrays to form a light emitting surface.

2. The method as set forth in claim 1, wherein each array includes at least two LED dies.

3. The method as set forth in claim 1, wherein the encapsulant includes one of organic and inorganic phosphor.

4. The method as set forth in claim 1, wherein the step of covering with the encapsulant includes one of:
dispensing the encapsulant onto LED dies, and
placing the encapsulant onto the LED dies via transfer molding techniques.

5. The method as set forth in claim 1, wherein the encapsulant is a hemisphere.

6. The method as set forth in claim 1, wherein the reflective layer includes one of:
a thin metal film,
dielectric multi-layer films, and
TiO₂ filled polymeric materials.

7. The method as set forth in claim 1, further including:
coating the encapsulant with the reflective layer via a lift-off technique.

8. The method as set forth in claim 1, wherein the step of disposing includes one of:
flip chip bonding the LED dies to the substrate, and
bonding the LED dies to a first bond pad and a top electrode reverse order wire to a second bond pad.

9. The method as set forth in claim 1, wherein the step of disposing includes one of:
connecting the LED dies of each array in series, and
connecting the LED dies of each array in parallel.

10. The method as set forth in claim 1, wherein the step of dicing includes one of:
laser cutting,
saw cutting, and
wire cutting.

11. An LED package fabricated by the method of claim 1.

12. The method as set forth in claim 11, wherein a thickness of the LED package is less than or equal to about 600 um.

13. The LED package as set forth in claim 11, wherein the substrate includes:
a core layer of a flexible material;
a first layer disposed at a core surface proximately to the LED dies; and
a second layer disposed at a core surface distally from the LED dies.

14. The method as set forth in claim 13, wherein the flexible core layer includes polyimide.

15. The method as set forth in claim 13, wherein the first and second layers include copper for correspondingly interconnecting the LED dies and preventing optical leakage.

16. The method as set forth in claim 13, wherein a thickness of the substrate is less than or equal to about 49 um.

17. The method as set forth in claim 12, wherein the LED dies include at least one of a near-UV or violet emitting LED.

18. A method of fabricating a thin light emitting diode (LED) backlight comprising:
fabricating a substrate including:
disposing a first metal layer on a first surface of a layer of flexible material, and
disposing a second metal layer on a second surface of the layer of flexible material;
disposing a first LED array, which includes at least two LED dies, proximately to the first metal layer;
disposing a second LED array, which includes a number of LED dies equal to a number of the first array LED dies, proximately to the first metal layer in close proximity and substantially parallel to the first array;
covering each pair of substantially paralleled LED dies of the first and second arrays by substantially transparent optical encapsulant;
disposing a reflective layer about the optical encapsulant; and
dicing the substrate along an axis extending in parallel and between the first and second LED arrays.

19. The method as set forth in claim 18, wherein the step of dicing includes:
laser cutting the substrate; and
omitting a step of subsequent polishing.

20. A light emitting diode (LED) package comprising:
a substrate which includes:
a layer of a flexible material,
a first metal layer disposed on a first surface of the flexible layer, and
a second metal layer disposed on a second surface of the flexible layer; and
an LED die disposed about the first metal layer and covered by substantially transparent optical encapsulant which is covered by a reflective layer for a UV to visible spectral region, a thickness of the LED package is less than or equal to about 600 um.
